(19) United States
(12) Patent Application Publication
(10) Pub. No.: US 2022/0045252 A1
(43) Pub. Date: Feb. 10, 2022

(54) BONDING DEVICE AND METHOD IN MICROCOMPONENT PROCESS AND WELDING-AGENT PLACING UNIT

(71) Applicant: CHONGQING KONKA PHOTOELECTRIC TECHNOLOGY RESEARCH INSTITUTE CO., LTD., Chongqing (CN)

(72) Inventors: Chunlin FAN, Chongqing (CN); Bin WANG, Chongqing (CN); Qing WANG, Chongqing (CN)

(21) Appl. No.: 17/479,600

(22) Filed: Sep. 20, 2021

Related U.S. Application Data
(63) Continuation of application No. PCT/CN2020/107191, filed on Aug. 5, 2020.

(51) Int. Cl. H01L 33/62; B23K 37/04

(52) U.S. Cl. CPC H01L 33/62; B23K 2101/40; H01L 2933/0066; B23K 37/04

(57) ABSTRACT

The disclosure herein relates to a bonding device and a bonding method used in a microcomponent process, and a welding-agent placing unit. The method includes the following. A microcomponent to-be-bonded is peeled from a substrate, picked up and transferred, by a transfer unit, the microcomponent to-be-bonded to a welding-agent placing unit so as to make the electrode to-be-bonded adhere to the molten welding agent from a welding-agent hole in the welding-agent placing unit. The microcomponent to-be-bonded with molten welding agent is transferred to a driving backplate so as to realize the bonding process between the microcomponent to-be-bonded and the driving backplate after cooling of welding agent.

### CROSS-REFERENCE TO RELATED APPLICATIONS

This application is a continuation of International Application No. PCT/CN2020/107191, filed on Aug. 5, 2020, the entire disclosure of which is incorporated herein by reference.

### TECHNICAL FIELD

This disclosure relates to the field of display technology, and more particularly to a bonding device and a bonding method for bonding a microcomponent to-be-bonded with a driving backplate used in a microcomponent process, and a welding-agent placing unit.

### BACKGROUND

Taking a micro light-emitting diode (Micro LED) as an example of a microcomponent, in a mass transfer process, bonding an electrode of the microcomponent to-be-bonded with an electrode of a backplate after peeling the microcomponent from a substrate remain a difficulty.

According to current technology, solid indium or tin is placed on the electrode of the backplate. Subsequently, the electrode of the microcomponent to-be-bonded is placed on the electrode of the backplate. The electrode of the microcomponent to-be-bonded is bonded with the electrode of the backplate by laser welding technology. This bonding method may cause damage to wirings of the microcomponent to-be-bonded and the driving backplate. In addition, due to high demand for registration accuracy, laser equipment needs to be used in a bonding process, which will lead to high costs.

### SUMMARY

In view of shortcomings of related art, disclosed herein are implementations of a bonding device and a bonding method used in a microcomponent process, and a welding-agent placing unit.

This disclosure provides a bonding device used in a microcomponent process, including a welding-agent placing unit disposed with a welding-agent hole, where the welding-agent hole is placed with molten welding agent. The bonding device further includes a transfer unit configured to pick up and transfer a microcomponent to-be-bonded, where the transfer unit is configured to pick up and transfer the microcomponent to-be-bonded into the welding-agent hole such that an electrode to-be-bonded adheres to the welding agent, and further configured to transfer the microcomponent to-be-bonded with the welding agent to a driving backplate for bonding.

Based on the same inventive concept, a bonding method used in a microcomponent process is also provided in this disclosure. The method includes the following. A microcomponent to-be-bonded is peeled from (lifted off) a substrate, picked up and transferred, by a transfer unit, the microcomponent to-be-bonded to a welding-agent placing unit so as to make the electrode to-be-bonded adhere to the molten welding agent from the welding-agent hole in the welding-agent placing unit. The microcomponent to-be-bonded with molten welding agent is transferred to a driving backplate so as to realize the bonding process between the microcomponent to-be-bonded and the driving backplate after cooling of the welding agent.

Based on the same inventive concept, a welding-agent placing unit is also provided in this disclosure. The welding-agent placing unit includes a body and a plurality of welding-agent holes defined in the body. The plurality of welding-agent holes are arranged in array in the body. Each of the plurality of welding-agent holes includes a welding-agent inducing hole and a welding-agent receiving hole communicating with the welding-agent inducing hole. The welding-agent inducing hole is configured to induce supplementary welding-agent to the welding-agent receiving hole.

### BRIEF DESCRIPTION OF THE DRAWINGS

FIG. 1 is a plan view of a welding-agent placing unit according to implementations of the present disclosure.

FIG. 2 is a cross-sectional view of a welding-agent placing unit of FIG. 1.

FIG. 3 is a side view of a transfer unit according to implementations of the present disclosure.

FIG. 4 is a plan view of a transfer unit in FIG. 3.

FIG. 5 is a view illustrating a bonding process between a microcomponent to-be-bonded and a driving backplate according to implementations of the present disclosure.

FIG. 6 is a schematic flowchart of a bonding method used in a microcomponent process according to implementations of the present disclosure.

### DESCRIPTION OF SOME ELEMENTS IN THE DRAWINGS

200: microcomponent to-be-bonded; 400: driving backplate; 210: electrode; 410: electrode of backplate; 10: welding-agent placing unit; 20: transfer unit; 11: welding-agent hole; 300: substrate; 111: welding-agent inducing hole; 112: welding-agent receiving hole; 23: drive shaft 23; 21: transfer plate 21; 22: protrusion 22; 211: first surface; 212: second surface.

### DETAILED DESCRIPTION

In order to facilitate the complete understanding of this disclosure, a detailed description will be provided hereinafter with reference to the accompanying drawings. Implementations are provided in this disclosure. However, this disclosure can be implemented in many different forms and is not limited to implementations described herein. On the contrary, the implementations are provided for more thorough and comprehensive understanding of this disclosure.

Unless otherwise defined, all technology and technical terms employed in this disclosure are identical to appreciation of those skilled in the art. It will be appreciated that the technical terms are described herein for the purpose of explaining this disclosure rather than limiting this disclosure.

Taking a micro light-emitting diode (Micro LED) or other types of microcomponent as an example of a microcomponent, in a mass transfer process, bonding an electrode with an electrode of a backplate after peeling the microcomponent to-be-bonded from a substrate by laser remain a difficulty.

It is desirable for this disclosure to provide a technical solution to the problem as described above. This disclosure aims to solve a technical problem of bonding an electrode of an microcomponent with an electrode of a backplate after peeling the electrode from a substrate. Detailed descriptions will be further illustrated below through implementations.

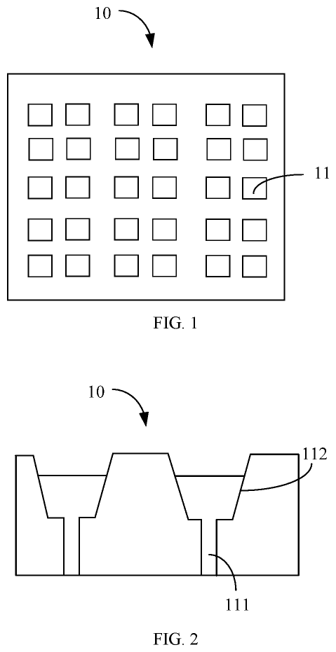

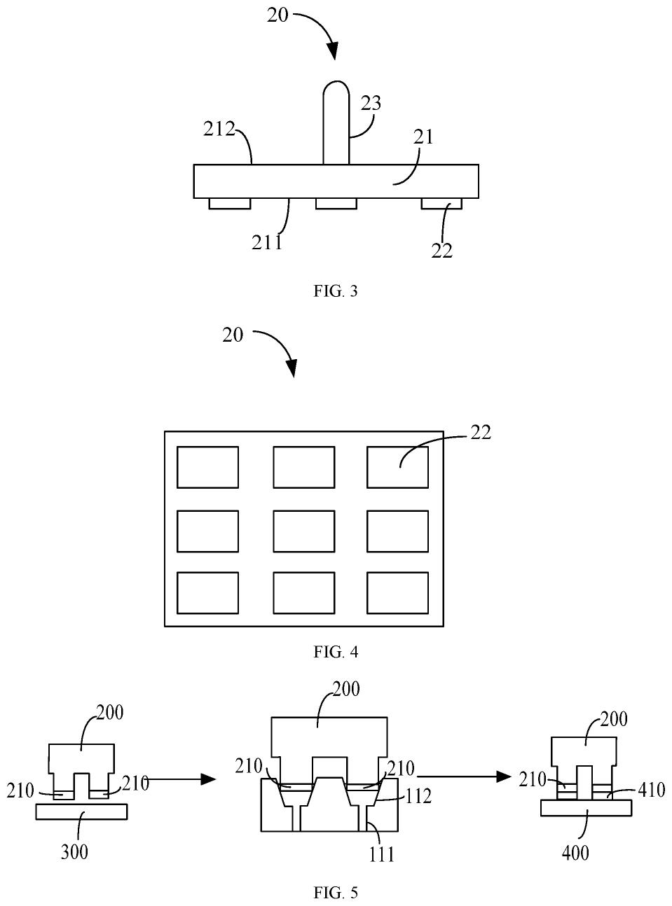

As illustrated from FIG. 1 to FIG. 5, a bonding device used in a microcomponent process is employed to bond a microcomponent to-be-bonded 200 with a driving backplate 400, where the microcomponent to-be-bonded 200 includes two electrodes 210. The two electrodes 210 can be located on the same side of the microcomponent to-be-bonded 200 or the opposite sides of the microcomponent to-be-bonded 200. In this implementation, the two electrodes 210 are located on the same side of the microcomponent to-be-bonded 200. The driving backplate 400 is disposed with electrodes of backplate 410 which correspond to the electrodes 210. Before the microcomponent to-be-bonded 200 is bonded with the driving backplate 400, the microcomponent to-be-bonded 200 is disposed on a substrate 300. The bonding device includes welding-agent placing unit 10 and transfer unit 20. The welding-agent placing unit 10 is defined with welding-agent hole 11 corresponding to each of the electrodes 210 of the microcomponent to-be-bonded 200. The welding-agent hole 11 is used to contain molten welding agent and maintain molten welding agent at preset temperature. The transfer unit 20 is configured to pick up and transfer microcomponent to-be-bonded 200. The transfer unit 20 picks up and transfers the microcomponent to-be-bonded 200 to the welding-agent hole 11 so as to make the electrode 210 of the microcomponent to-be-bonded 200 adhere to welding agent. Subsequently, the microcomponent to-be-bonded 200 with welding-agent is transferred to a driving backplate 400 for bonding.

In this way, fast bonding between the microcomponent to-be-bonded and the driving backplate is realized, damage arisen from current laser welding technique to wirings of the microcomponent to-be-bonded and the driving backplate is reduced, and the costs can also be reduced without the usage of laser equipment.

In one implementation, the microcomponent to-be-bonded 200 can be a Micro LED which has any of a normal chip structure, a vertical chip structure, or a flip-chip structure.

In one implementation, if the microcomponent to-be-bonded 200 has a flip-chip structure, the two electrodes 210 can be located on the same side of the microcomponent to-be-bonded 200. The substrate 300 is a transitory substrate, for example, a sapphire substrate or other types of substrate, which is not limited thereto. In some implementations, if the microcomponent to-be-bonded 200 has a normal chip structure, the two electrodes 210 can be located on the same side of the microcomponent to-be-bonded 200. The substrate 300 can be a growth substrate and the transitory substrate and the growth substrate can be located on the opposite sides of the microcomponent to-be-bonded 200. In some implementations, If the microcomponent to-be-bonded 200 has a vertical chip structure and the two electrodes 210 can be located on the opposite sides of the microcomponent to-be-bonded 200, the substrate 300 can be a growth substrate and the transitory substrate and the growth substrate can be located on the opposite sides of the microcomponent to-be-bonded 200. One of the two electrodes 210 is positioned adjacent to the transitory substrate. The other of the two electrodes 210 is positioned adjacent to the growth substrate.

In one implementation, the method of peeling the electrode 210 from the transitory substrate 300 can be but not limited to laser melting and heat melting, which is not limited thereto.

In one implementation, the welding-agent hole 11 includes a welding-agent inducing hole 111 and a welding-agent receiving hole 112 communicating with the welding-agent inducing hole 111. The welding-agent inducing hole 111 is configured to induce supplementary welding-agent to the welding-agent receiving hole 112.

The welding-agent inducing hole 111 has a shape of straight hole, which is located at the bottom of the welding-agent placing unit 10. The welding-agent receiving hole 112 is located on the top of the welding-agent placing unit 10. The welding-agent inducing hole 111 communicates with the welding-agent receiving hole 112. The welding-agent inducing hole 111 is configured to induce supplementary welding-agent to the welding-agent receiving hole 112. After the electrode 210 of the microcomponent to-be-bonded 200 adheres to welding agent, the welding-agent inducing hole 111 will simultaneously induce supplementary welding-agent to the welding-agent receiving hole 112 to maintain welding-agent at a fixed liquid level.

In this way, the welding-agent inducing hole 111 can induce supplementary welding-agent to the welding-agent receiving hole 112.

In one implementation, the welding-agent receiving hole 112 has a cross-section of an inverted trapezium shape. As an example, as illustrated in FIG. 2, the welding-agent receiving hole 112 can have an inverted longitudinal section that is in a trapezium shape. It should be understood that, in other implementations, the welding-agent receiving hole 112 can have an inverted cross-section that is in a trapezium shape, which is not limited thereto.

Therefore, the welding-agent receiving hole 112 with the shape of trapezium can control position of bonding between the electrode 210 and the welding-agent to ensure each electrode 210 adheres to the same amount of welding agent.

Alternatively, in one implementation, the welding-agent inducing hole 111 is located in the middle of the bottom part of the welding-agent receiving hole 112. In this way, the welding-agent inducing hole 111 can induce the welding-agent more evenly. It should be understood that, in other implementations, the welding-agent inducing hole 111 can also be located in other positions of the bottom part of the welding-agent receiving hole 112, which is not limited thereto.

As an implementation, the welding-agent hole 11 is implemented as a plurality of welding-agent holes. The plurality of welding-agent holes 11 are arranged in array in the welding-agent placing unit 10.

In this way, the plurality of electrodes 210 of the microcomponent to-be-bonded 200 can adhere to the welding-agent individually and simultaneously.

In one implementation, the welding-agent placing unit 10 is defined with 6*6 the welding-agent holes 11. In other implementations, the number of the welding-agent holes 11 is not limited thereto and can be defined according to actual demand.

Alternatively, in one implementation, if the microcomponent to-be-bonded 200 has the normal chip structure or the flip-chip structure, a distance between two adjacent welding-agent holes 11 equals that between two electrodes of a microcomponent to-be-bonded 200.

Alternatively, in one implementation, if the microcomponent to-be-bonded 200 has the vertical chip structure, a distance between two adjacent welding-agent holes 11 equals that between two electrodes of two adjacent microcomponents to-be-bonded 200.

Alternatively, in one implementation, the transfer unit 20 includes a control module (not shown in drawings), a drive shaft 23, a transfer plate 21, and at least one protrusion 22. The transfer plate 21 has a first surface 211 and a second surface 212 opposite to the first surface 211. The at least one protrusion 22 is disposed on the first surface 211 of the transfer plate 21. The drive shaft 23 is disposed on the second surface 212 of the transfer plate 21. The control module drives, through the drive shaft 23, the transfer plate 21 to move so as to make the at least one protrusion 22 move in a three-dimensional direction (for example, accuracy control ≤1 μm) to pick up and transfer the microcomponent to-be-bonded 200. Specifically, the protrusion 22 picks up the microcomponent to-be-bonded 200 from substrate 300. Subsequently, the microcomponent to-be-bonded 200 is transferred to the welding-agent placing unit 10, so that the electrode 210 of the microcomponent to-be-bonded 200 is inserted into the welding-agent hole 11 to adhere to welding agent. Then, microcomponent to-be-bonded 200 is picked up from welding-agent hole 11 and fast bonded to driving backplate 400.

Alternatively, in one implementation, when the substrate 300 is the growth substrate, the electrode 210 adheres to the transitory substrate through an adhesive layer. Therefore, the transitory substrate can be implemented as the transfer plate 21, and the adhesive layer between the electrode 210 and the transitory substrate can be implemented as the at least one protrusion 22 so as to connect the drive shaft with the transitory substrate. The transitory substrate is driven to make the microcomponent to-be-bonded 200 be transferred to the driving backplate 400 for bonding.

In one implementation, the electrode 210 of the microcomponent to-be-bonded 200 is inserted into the welding-agent hole 11 to adhere to welding-agent for a first duration (for example, 5 seconds to 10 seconds or other periods of time). In this way, the electrode 210 can have a full access to welding-agent in welding-agent receiving hole 112.

In one implementation, the microcomponent to-be-bonded 200 is picked up from the corresponding welding-agent hole 11 for a second duration (for example, 1 second to 3 seconds or other periods of time). In this way, redundant welding-agent can be dropped to avoid waste of welding agent.

In one implementation, the protrusion 22 is made of any of: polydimethylsiloxane, photolysis glue, or pyrolysis glue. If the protrusion 22 is made of polydimethylsiloxane, an adhesive force between the protrusion 22 and the microcomponent to-be-bonded 200 is less than that between the microcomponent to-be-bonded 200 and the driving back plate 400. In this way, when the protrusion 22 transfers the microcomponent to-be-bonded 200 to the driving back plate 400 for bonding, the protrusion 22 can be peeled from the microcomponent to-be-bonded 200.

In one implementation, the protrusion 22 is implemented as a plurality of protrusions. The plurality of protrusions are arranged in array. In this implementation, the protrusion 22 is arranged in a 3*3 array. It should be understood that, in other implementations, the number of protrusion 22 is not limited thereto. The distance between two adjacent protrusions 22 equals that between two adjacent welding-agent holes 11.

In this way, a mass transfer and mass bonding of the microcomponent to-be-bonded 200 can be achieved.

In one implementation, a distance between the driving backplate 400 and the welding-agent placing unit 10 ranges from 10 mm to 100 mm. Process atmosphere ranges from 110 □ to 130□ or so to ensure the welding-agent which adheres to the electrode 210 will not cure before the electrode 210 is transferred to the driving back plate 400. The microcomponent to-be-bonded 200 and the driving back plate 400 can thus be bonded.

In one implementation, after the microcomponent to-be-bonded 200 is bonded with the driving back plate 400, the welding-agent between the microcomponent to-be-bonded 200 and the driving back plate 400 is cooled and cured, so that firm connection between the microcomponent to-be-bonded 200 and the driving back plate 400 can be achieved through the welding agent.

Alternatively, in one implementation, a method used in the cooling and curing process of welding-agent between the microcomponent to-be-bonded 200 and the driving back plate 400 is air compression.

Alternatively, in one implementation, after cooling and curing welding-agent between the microcomponent to-be-bonded 200 and the driving back plate 400, bonding effect is detected, through the optical detection equipment, in the aspect of structure and electrical connection. If bonding performance is detected to be defective, poorly performed chip will be peeled from the driving backplate 400 for a new bonding. The new bonding can be peeling solid welding-agent from the poorly performed electrode 210 of the microcomponent to-be-bonded 200 and bonding the microcomponent to-be-bonded 200 with driving backplate 400 again. The new bonding can also be bonding a new microcomponent to-be-bonded 200 with driving backplate 400. Subsequently, bonding effect is detected again, through the optical detection equipment, in aspects of structure and electrical connection. This process will be repeated until bonding effect is detected to be good.

Alternatively, in one implementation, the optical detection equipment can include but is not limited to automatic optical inspection equipment and auto-probe station. The automatic optical inspection equipment is used to detect effect in an aspect of structure. The auto-probe station is used to detect effect in an aspect of electrical connection. If the bonding effect in the aspect of structure is detected, through the automatic optical inspection equipment, to be good and the bonding effect in the aspect of electrical connection is detected, through the auto-probe station, to be good, the bonding effect can be confirmed to be good.

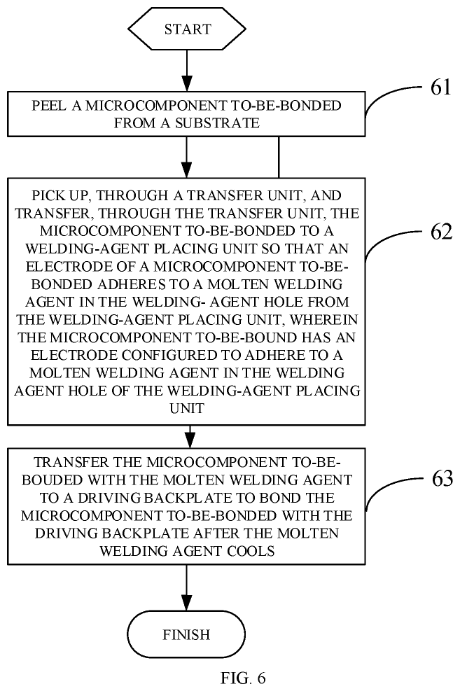

FIG. 6 is a schematic flowchart of a bonding method used in a microcomponent process according to implementations of the present disclosure. A bonding method used in a microcomponent process is also provided. The sequence of the bonding method is not limited hereinafter and can be adjusted according to actual demand. The bonding method includes the following operations.

At block 61, a microcomponent to-be-bonded 200 is peeled from a substrate 300.

Alternatively, in one implementation, if the microcomponent to-be-bonded 200 has the flip-chip structure, two electrodes 210 can be located on the same side of the microcomponent to-be-bonded 200. The substrate 300 is a transitory substrate, for example, sapphire substrate or other types of substrate, which is not limited thereto.

The electrode 210 can be peeled from the substrate 300 by laser melting and heat melting, which is not limited thereto.

At block 62, a microcomponent to-be-bonded 200 is picked up and transferred, through a transfer unit 20, to a welding-agent placing unit 10 so as to make electrodes of the microcomponent to-be-bonded 200 adhere to molten welding agent in a welding-agent hole 11 from the welding-agent placing unit 10.

At block 63, a microcomponent to-be-bonded 200 which adheres to the molten welding agent is transferred to a driving back plate 400. The microcomponent to-be-bonded 200 is bonded with the driving back plate 400 after the completion of the cooling process of the welding agent.

The control module drives, through the drive shaft 23, the transfer plate 21 to move so as to make the at least one protrusion 22 move in three-dimensional direction (for example, accuracy control ≤1 μm) to pick up and transfer the microcomponent to-be-bonded 200. Specifically, the protrusion 22 picks up the microcomponent to-be-bonded 200 from substrate 300. Subsequently, the microcomponent to-be-bonded 200 is transferred to the welding-agent placing unit 10. The electrode 210 of the microcomponent to-be-bonded 200 is inserted into the welding-agent hole 11 to adhere to welding agent. Then, microcomponent to-be-bonded 200 is picked up from welding-agent hole 11 and fast bonded to driving backplate 400.

In this way, fast bonding between microcomponent to-be-bonded 200 and driving backplate 400 is realized in this disclosure to reduce the damage arisen from current laser welding technique to circuit lines of the microcomponent to-be-bonded 200 and the driving backplate 400. Without the employment of laser equipment, the costs can also be saved.

Alternatively, in one implementation, process atmosphere of molten welding agent in the welding-agent placing unit 10 should be vacuum. Process temperature of molten welding agent in the welding-agent placing unit 10 should maintain a preset temperature. The preset temperature herein is a temperature where welding-agent is maintained at a molten state. The welding-agent can be but not limited to indium, tin or other types of welding agent. Taking tin as an example, the process temperature of the welding-agent should range from 120□ to 156.7□ and the process atmosphere is vacuum.

Alternatively, in one implementation, the welding-agent placing unit 10 can heat welding-agent herein through an external device or its own heating device. In this way, the process temperature of molten welding agent in the welding-agent placing unit 10 can maintain the preset temperature.

Alternatively, in one implementation, the electrode 210 of the microcomponent to-be-bonded 200 is inserted into the welding-agent hole 11 to adhere to welding-agent for a first preset duration (for example, 5 seconds to 10 seconds or other period of time). In this way, the electrode 210 can have a full access to the welding-agent in welding-agent receiving hole 112.

Alternatively, in one implementation, the microcomponent to-be-bonded 200 is picked up from the welding-agent hole 11 for a second preset duration (for example, 1 second to 30 seconds or other period). In this way, welding-agent dropping process can be conducted to avoid waste of welding agent.

Alternatively, in one implementation, pitch between the driving backplate 400 and the welding-agent placing unit 10 ranges from 10 mm to 100 mm. The process atmosphere ranges 110□ to 130□ or so to ensure the welding-agent which adheres to the electrode 210 will not cure before the electrode 210 is transferred to the driving back plate 400. The microcomponent to-be-bonded 200 and the driving back plate 400 can thus be bonded.

Alternatively, in one implementation, after the bonding of the microcomponent to-be-bonded 200 with the driving back plate 400, welding-agent between the microcomponent to-be-bonded 200 and the driving back plate 400 is cooled and cured. Firm connection between the microcomponent to-be-bonded 200 and the driving back plate 400 can be achieved through welding agent.

Alternatively, in one implementation, a method used in the cooling and curing process of welding-agent between the microcomponent to-be-bonded 200 and the driving back plate 400 can be air compression.

Alternatively, in one implementation, the method further includes: detecting bonding effect and peeling the poorly performed microcomponent to-be-bonded 200 from the driving back plate 400 when bonding performance is detected to be defective.

Alternatively, in one implementation, after cooling and curing welding-agent between the microcomponent to-be-bonded 200 and the driving back plate 400, bonding effect is detected, through the optical detection equipment, in the aspect of structure and electrical connection. If bonding performance is detected to be defective, the poorly performed microcomponent to-be-bonded 200 will be peeled from the driving backplate 400 for a new bonding. It should be understood that the meaning of the new bonding can be peeling solid welding-agent from the poorly performed electrode 210 of the microcomponent to-be-bonded 200 and bonding the microcomponent to-be-bonded 200 with driving backplate 400 again. The meaning of the new bonding can also be bonding a new microcomponent to-be-bonded 200 with driving backplate 400. Subsequently, bonding effect is detected again, through the optical detection equipment, in the aspect of structure and electrical connection. The process will be repeated until bonding effect is detected to be good.

Alternatively, in one implementation, the optical detection equipment can include but is not limited to automatic optical inspection equipment and auto-probe station. The automatic optical inspection equipment is used to detect the effect in the aspect of structure. The auto-probe station is used to detect the effect in the aspect of electrical connection. If the bonding effect in the aspect of structure is detected, through the automatic optical inspection equipment, to be good and the bonding effect in the aspect of electrical connection is detected, through the auto-probe station, to be good, the bonding effect can be confirmed to be good.

Therefore, it is possible to effectively avoid poor performance.

It should be understood that the application of this disclosure is not limited to the examples as described above. For those of ordinary skill in the art, improvement or transformation can be made according to the examples as described above, all of which fall within the protection scope of this disclosure.

What is claimed is:

1. A bonding device used in a microcomponent process, comprising:
a welding-agent placing unit disposed with a welding-agent hole, wherein the welding-agent hole is placed with molten welding agent; and
a transfer unit configured to pick up and transfer a microcomponent to-be-bonded, wherein the transfer unit is configured to pick up and transfer the microcomponent to-be-bonded into the welding-agent hole such that an electrode of a microcomponent to-be-bonded adheres to the welding agent, and further configured to transfer the microcomponent to-be-bonded with the welding-agent to a driving backplate for bonding.

2. The bonding device of claim 1, wherein the welding-agent hole comprises a welding-agent inducing hole and a welding-agent receiving hole which communicates with the welding-agent inducing hole, and the welding-agent inducing hole is configured to induce supplementary welding-agent to the welding-agent receiving hole.

3. The bonding device of claim 2, wherein the welding-agent receiving hole has an inverted cross-section that is in a trapezium shape.

4. The bonding device of claim 2, wherein the welding-agent hole is implemented as a plurality of welding-agent holes, and the plurality of welding-agent holes are arranged in array in the welding-agent placing unit.

5. The bonding device of claim 1, wherein the welding-agent inducing hole is located in the middle of a bottom part of the welding-agent receiving hole.

6. The bonding device of claim 1, wherein when the microcomponent to-be-bonded has a normal chip structure or the flip-chip structure, a distance between two adjacent welding-agent holes equals that between two electrodes of a microcomponent to-be-bonded.

7. The bonding device of claim 1, wherein when the microcomponent to-be-bonded has a vertical chip structure, a distance between two adjacent welding-agent holes equals that between two electrodes of two adjacent microcomponents to-be-bonded.

8. The bonding device of claim 1, wherein the transfer unit comprises a drive shaft, a transfer plate, and at least one protrusion, the transfer plate has a first surface and a second surface opposite to the first surface, the at least one protrusion is disposed on the first surface of the transfer plate, and the drive shaft is disposed on the second surface of the transfer plate.

9. The bonding device of claim 8, wherein the protrusion is made of any of: polydimethylsiloxane, photolysis glue, or pyrolysis glue.

10. The bonding device of claim 9, wherein when the protrusion is made of polydimethylsiloxane, an adhesive force between the protrusion and the microcomponent to-be-bonded is weaker than that between the microcomponent to-be-bonded and the driving backplate.

11. A bonding method in a microcomponent process, comprising:
peeling a microcomponent to-be-bonded from a substrate;
picking up, through a transfer unit, and transferring, through the transfer unit, the microcomponent to-be-bonded to a welding-agent placing unit so that an electrode of a microcomponent to-be-bonded adheres to a molten welding agent in the welding-agent hole from the welding-agent placing unit, wherein the microcomponent to-be-bonded has an electrode configured to adhere to a molten welding agent in the welding-agent hole of the welding-agent placing unit; and
transferring the microcomponent to-be-bonded with the molten welding agent to a driving backplate to bond the microcomponent to-be-bonded with the driving backplate after the molten welding agent cools.

12. The bonding method of claim 11, further comprising:
inserting the electrode of the microcomponent to-be-bonded into the welding-agent hole to adhere to welding-agent for a first preset duration.

13. The bonding method of claim 11, further comprising:
removing the microcomponent to-be-bonded from the welding-agent hole of the welding-agent placing unit and maintaining the microcomponent to-be-bonded with welding-agent above the welding-agent hole for a second preset duration.

14. The bonding method of claim 11, further comprising:
heating the welding-agent placing unit to make welding-agent contained in the welding-agent placing unit in a molten state and to get a vacuum process atmosphere.

15. The bonding method of claim 11, further comprising:
cooling and curing the welding-agent between the microcomponent to-be-bonded and the driving backplate after the microcomponent to-be-bonded is transferred to the driving backplate.

16. The bonding method of claim 11, further comprising:
detecting bonding performance;
peeling a microcomponent with defective bonding from the driving backplate when the bonding is detected to be defective.

17. A welding-agent placing unit, comprising
a body; and
a plurality of welding-agent holes defined in the body, wherein the body defines a plurality of welding-agent holes, the plurality of welding-agent holes are arranged in array in the body, each of the plurality of welding-agent holes comprises a welding-agent inducing hole and a welding-agent receiving hole communicating with the welding-agent inducing hole, and the welding-agent inducing hole is configured to induce supplementary welding-agent to the welding-agent receiving hole.

18. The welding-agent placing unit of claim 17, wherein the welding-agent receiving hole has a cross-section that is in a trapezium shape.

19. The welding-agent placing unit of claim 17, wherein the welding-agent hole is implemented as a plurality of welding-agent holes, and the plurality of welding-agent holes are arranged in array in the welding-agent placing unit.

20. The welding-agent placing unit of claim 17, wherein the welding-agent inducing hole is located in the middle of a bottom part of the welding-agent receiving hole.
